(19) United States
(12) Patent Application Publication
(10) Pub. No.: US 2013/0017956 A1
(43) Pub. Date: Jan. 17, 2013

(54) METHOD OF FORMING SUPERCONDUCTING WIRE

(71) Applicants: Sang Im Yoo, Seoul (KR); Jung-Woo Lee, Seoul (KR)

(72) Inventors: Sang Im Yoo, Seoul (KR); Jung-Woo Lee, Seoul (KR)

(21) Appl. No.: 13/483,573

(22) Filed: May 30, 2012

(30) Foreign Application Priority Data
Jul. 14, 2011 (KR) 10-2011-0069785

(51) Int. Cl. H01L 39/24

(52) U.S. Cl. 505/434; 427/62

(57) ABSTRACT

Methods of forming a superconducting wire are provided. The method may include dissolving a superconducting material in an acid not including fluorine to form a superconducting precursor solution, providing the superconducting precursor solution on a substrate to form a superconducting precursor layer, and controlling an oxygen partial pressure of a processing chamber provided with the substrate and/or a temperature of the substrate in order that the superconducting precursor layer partially have a liquid phase, thereby forming an epitaxial superconducting layer on the substrate.

### CROSS-REFERENCE TO RELATED APPLICATIONS

This U.S. non-provisional patent application claims priority under 35 U.S.C. §119 to Korean Patent Application No. 10-2011-0069785, filed on Jul. 14, 2011, the entirety of which is incorporated by reference herein.

### BACKGROUND

The inventive concept relates to a superconducting wire.

A superconductor may have an electric resistance approaching 0 (zero) at a low temperature, so that a large current can pass through the superconductor. Recently, various researches have been conducted for the second generation high temperature superconductor forming a superconducting layer on a thin buffer layer having a biaxially aligned textured structure or a metal substrate. The second generation high temperature superconductor has more excellent current transfer ability than a general metal wire. The second generation high temperature superconductor may be used in various fields such as a power system having low power loss, a magnetic resonance imaging (MRI), a superconducting magnetic levitation train, and a superconducting propulsion ship.

### SUMMARY

Embodiments of the inventive concept may provide methods of forming a superconducting wire by a fluorine free metal organic deposition method.

According to embodiments of the inventive concepts, a method of forming a superconducting wire may include: dissolving a superconducting material in an acid not including fluorine to form a superconducting precursor solution; providing the superconducting precursor solution on a substrate to form a superconducting precursor layer; and controlling an oxygen partial pressure of a processing chamber provided with the substrate and/or a temperature of the substrate such that the superconducting precursor layer partially have a liquid phase, thereby forming an epitaxial superconducting layer on the substrate.

In some embodiments, the acid not including fluorine may include propionic acid.

In other embodiments, the superconducting material may be a superconducting powder.

In still other embodiments, the superconducting powder may include rare earth element, barium, and copper.

In even other embodiments, controlling an oxygen partial pressure of a processing chamber provided with the substrate and/or a temperature of the substrate may include: heating the substrate under an oxygen atmosphere to about 825° C. or more.

### BRIEF DESCRIPTION OF THE DRAWINGS

The inventive concept will become more apparent in view of the attached drawings and accompanying detailed description.

FIG. 1 is a flow chart illustrating a method of forming a superconducting wire according to embodiments of the inventive concept;

FIG. 2 is a diagram for explaining a thermal treatment of a superconducting material according to embodiments of the inventive concept;

FIG. 3 shows a phase diagram of an yttrium-barium-copper oxide (YBCO);

FIG. 4 shows a cross-sectional view of a superconducting wire formed according to embodiments of the inventive concept;

FIG. 5 is a phase diagram of an YBCO illustrating a method of forming a superconducting wire according to some embodiments of the inventive concept;

FIG. 6 is a phase diagram of an YBCO illustrating a method of forming a superconducting wire according to other embodiments of the inventive concept; and

FIGS. 7 and 8 show crystal property and electric physical property of a superconducting wire formed according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

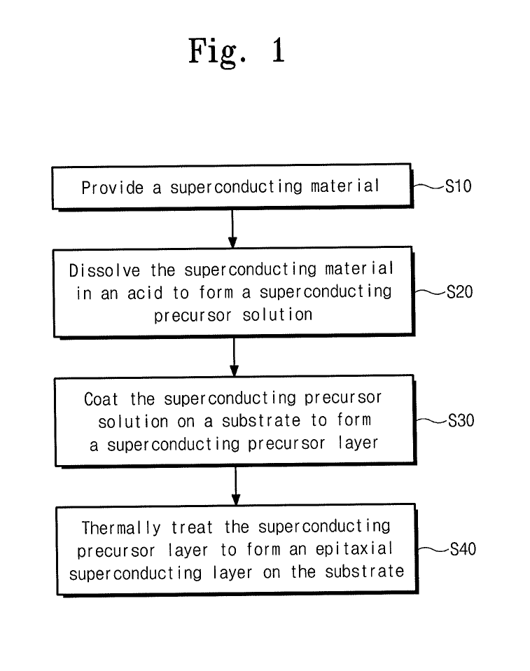

FIG. 1 is a flow chart illustrating a method of forming a superconducting wire according to embodiments of the inventive concept. A method of forming a superconducting wire according to the inventive concept will be approximately described with reference to FIG. 1.

In a first step (S10), a superconducting material is provided. The superconducting material may be a superconducting powder. The superconducting material may include rare-earth element, barium, and copper. In the inventive concept, yttrium-barium-copper oxide (YBCO) and samarium-barium-copper oxide (SmBCO) may be used as an example of the superconducting material. However, the inventive concept is not limited thereto. In other words, the superconducting material may include rare earth element-barium-copper oxide (REBCO). The REBCO may be represented as RE₁₊ₓBa₂₋ₓCu₃O_{7-y} (0≦x≦0.5, 0≦y≦0.5). The rare earth element (RE) may include one of yttrium (Y), a lanthanide element, and any combination thereof. The lanthanide element may include at least one of lanthanum (La), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

In a second step (S20), the superconducting material is dissolved in an acid not including fluorine, to form a superconducting precursor solution. The acid not including fluorine may include propionic acid. If the superconducting material is YBCO powder, a reaction formula between propionic acid and YBCO powder may be represented as the following reaction formula 1.

YBa₂Cu₃O_{6.5}+13CH₃CH₂COOOH→Y(CH₃CH₂COO)₃+2Ba(CH₃CH₂COO)₂+3Cu(CH₃CH₂COO)₂+13/2H₂O [Reaction formula 1]

The superconducting precursor solution may include Y(CH₃CH₂COO)₃, 2Ba(CH₃CH₂COO)₂, and 3Cu(CH₃CH₂COO)₂. The superconducting precursor solution may be stirred until YBCO powder is completely dissolved. The superconducting precursor solution may be dried at a temperature of about 80° C. Methanol may be added into the superconducting precursor solution, so that the superconducting precursor solution including the methanol may become a dark blue solution. According to the inventive concept, other additional materials are not provided to the superconducting precursor solution.

In a third step (S30), the superconducting precursor solution is provided on a substrate, to form a superconducting precursor layer. The superconducting precursor solution may be in an amorphous state which is not crystallized. The substrate may be a wire substrate. The wire substrate may be a base material having a biaxially aligned textured structure. The base material may include a metal or single-crystalline substrate having a textured structure, or an oxide buffer layer having a textured structure and provided on a metal substrate. The metal or single-crystalline substrate may be formed of a cubic system metal of a rolled and thermally treated nickel (Ni), a Ni-based alloy (e.g., Ni—W, Ni—Cr, Ni—Cr—W, etc.), silver (Ag), a silver alloy, or a Ni—Ag complex. The oxide buffer layer may be a superconducting middle layer, MgO, LaAlO₃, LaMnO₃, or SrTiO₃. The oxide buffer layer can prevent reaction of the base material and the superconducting material thereon and transfer crystal property of the biaxially aligned textured structure.

The superconducting precursor layer may be formed by at least one of various methods. For example, the superconducting precursor layer may be formed by a metal organic deposition (MOD) method or a sol-gel method.

In a fourth step (S40), the superconducting precursor layer may be thermally treated to form an epitaxial superconducting layer on the wire substrate.

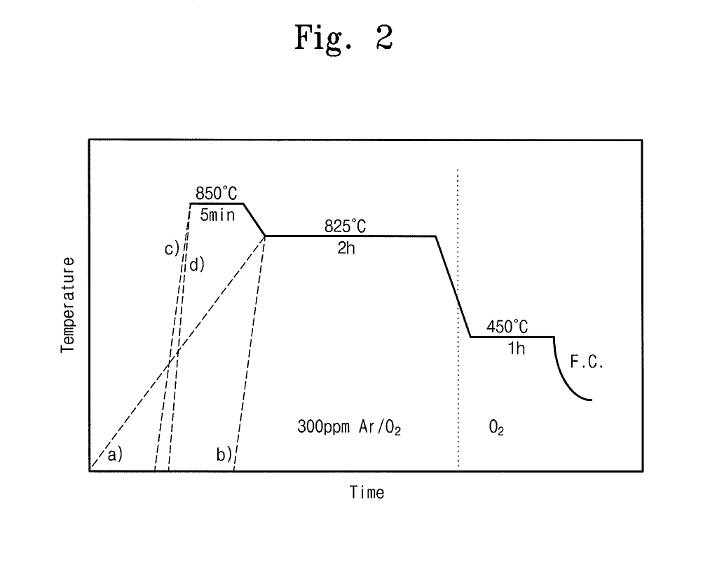

An example of the thermal treatment process of the superconducting precursor layer will be described. FIG. 2 is a diagram for explaining a thermal treatment of a superconducting material according to embodiments of the inventive concept. Reference designators (a) and (b) explain general thermal treatment processes, and reference designators (c) and (d) explain partial melting processes according to the inventive concept. Ramping rates of the processes (a), (b), (c), and (d) were about 20° C./min, about 240° C./min, about 240° C./min, and about 850° C./min, respectively.

First, the superconducting precursor layer is pyrolized under an oxygen atmosphere at a temperature of about 400° C. Referring to FIG. 2, the pyrolized superconducting precursor layer may be heated to be partially melted. To achieve this, an oxygen partial pressure of a processing chamber including the wire substrate may be controlled and/or a temperature of the wire substrate may be controlled. The heating temperature may be equal to or greater than about 825° C. Particularly, the heating temperature may be about 850° C. After the wire substrate is heated to the temperature of about 825° C. or more, the wire substrate may be cooled.

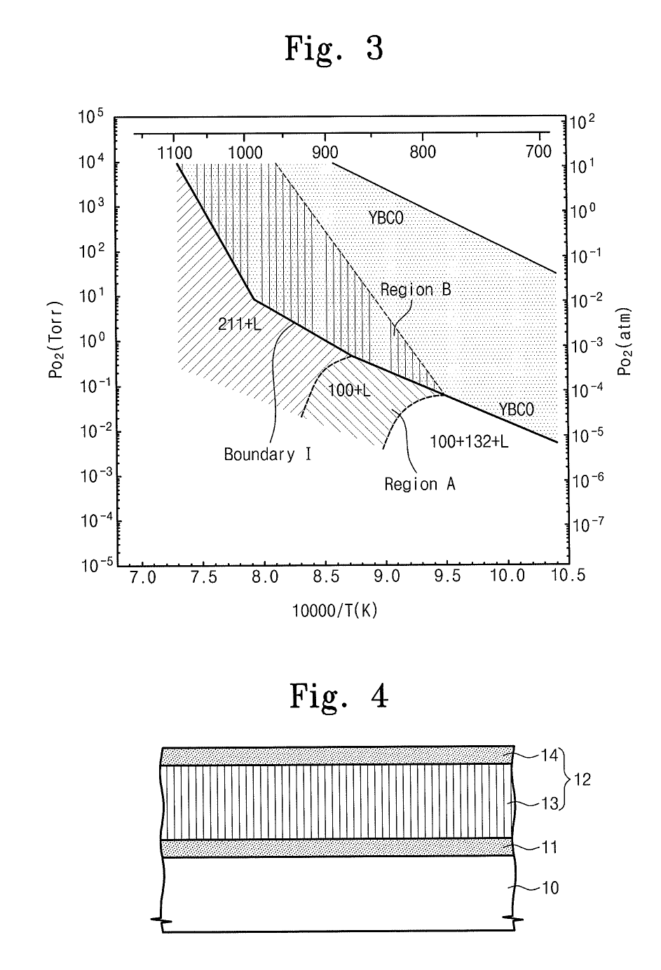

The partial melting process according to the inventive concept will be described in more detail. FIG. 3 shows a phase diagram of an YBCO.

Referring to FIG. 3, the REBCO being the superconducting precursor layer formed in the third step (S30) may include RE₂BaCuO₅ (hereinafter, referred to as “211”), RE₂O₃ (hereinafter, referred to as “100”), REBa₃Cu₂O₂ (hereinafter, referred to as “132”), and a liquid phase (hereinafter, referred to as “L”). Here, the “L is the liquid phase of which the main elements are Ba, Cu, and O. Additionally, the “L” is the liquid phase into which the rare earth element (RE) can be melted. A gray area has a thermodynamically stable REBCO.

In the fourth step (S40), the wire substrate having the superconducting precursor layer is thermally treated. The oxygen partial pressure and/or the thermal treatment temperature may be controlled to have the liquid phase (“L”) of which the main elements are Ba, Cu, and O of the decomposition elements of the REBCO and into which the rare earth element (RE) can be melted. At this time, the REBCO may be formed through a region where the “L” and the “100” coexist (a region A of FIG. 3). The oxygen partial pressure and/or the thermal treatment temperature may be controlled, so that the REBCO may pass through a boundary I from the region A of FIG. 3. Thus, a stable epitaxial REBCO layer can be formed by reaction of the “100” in the “L” of the liquid phase. In more detail, nuclei can be generated on a surface of the wire substrate from the “100” coexisting in the “L”, and then The REBCO layer can be epitaxial-grown (a region B of FIG. 3).

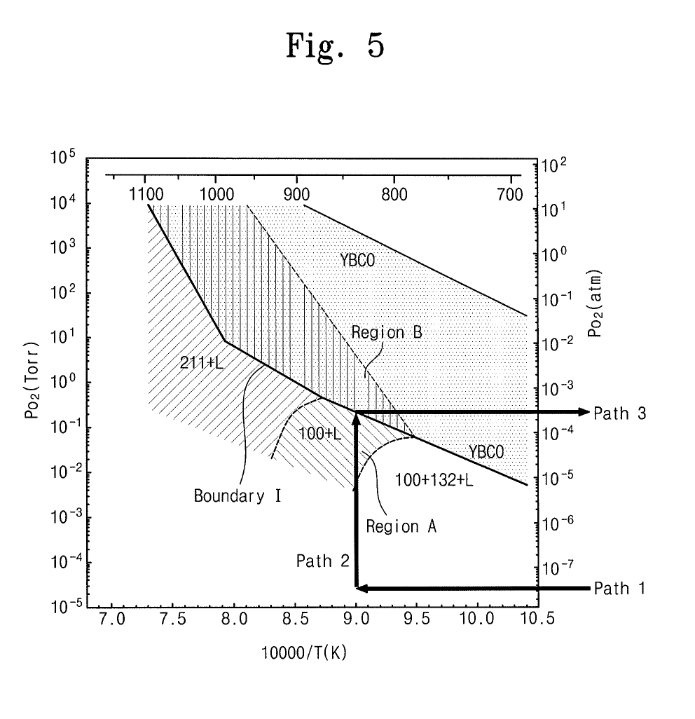

FIG. 4 shows a cross-sectional view of a superconducting wire formed according to embodiments of the inventive concept. Referring to FIG. 4, the REBCO layer 12 formed on the wire substrate 10 having the buffer layer 11 by the above method may include a first portion 13 adjacent to the buffer layer 11 and having a superconducting phase, and a second portion 14 disposed on the first portion 13 and having a phase different from the superconducting phase. In the first portion 13, a ratio of rare earth: barium: copper may be 1:2:3. In the second portion 14, a ratio of rare earth: barium: copper may be different from a ration of 1:2:3. This is because the superconducting precursor remains in an upper portion of the REBCO layer while the REBCO layer is epitaxial-grown from the “L” and the “100” in a lower portion of the REBCO layer. Thus, the upper portion of the REBCO layer, which is the second portion 14 and finally formed, may include a non-stoichiometric oxide corresponding to vestiges of the superconducting precursor. The second portion 14 may include at least one phase having a crystal structure different from that of the first portion 13. The first portion 13 may contain additional “100” particles.

On the other hand, in the aforementioned method of forming the REBCO layer, the superconducting precursor layer may be formed to have a ratio of rare earth: barium: copper which is 1:x:3 (0≦x≦2), for example, 1:1.5:3. Generally, a REBCO precursor having a ratio of 1:2:3 has an unstable structure decomposed in the air. On the other hand, the REBCO precursor having a ratio of, for example, 1:1.5:3 may have a stable structure in the air. Thus, the REBCO precursor layer having the ratio of 1:2:3 has to be kept under a vacuum before the thermal treatment process, but the REBCO precursor layer having the ratio of 1:1.5:3 can be exposed in the air before the thermal treatment process. The REBCO precursor layer having the ratio of 1:x:3 (0≦x≦2) may be formed into the REBCO superconducting layer which includes the first portion 13 of which the ratio of rare earth: barium: copper is 1:2:3, and the second portion 14 of which the ratio of rare earth: barium: copper is different from 1:2:3. In this case, the second portion 14 may include BaCu₂O₂ (hereinafter, referred to as “012”) of a solid phase. The “100” was consumed during the epitaxial growth of the first portion 13.

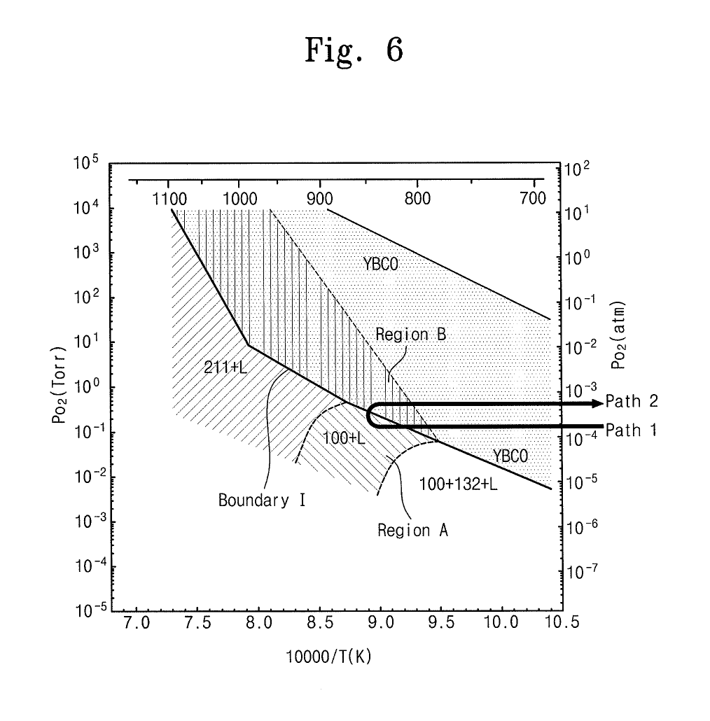

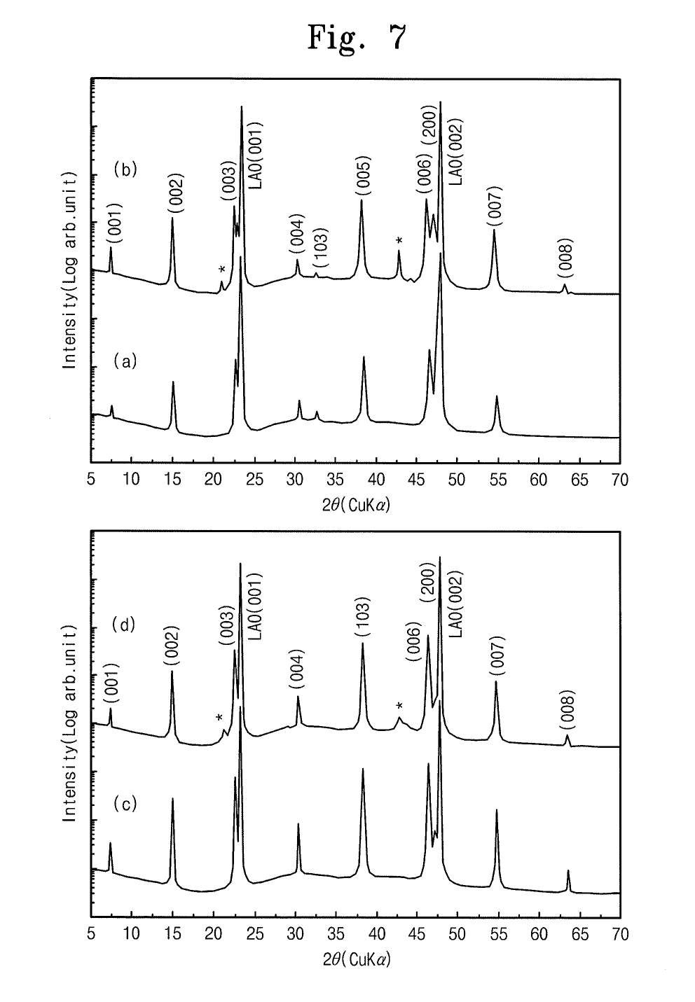

A method of a superconducting wire according to inventive concept will be described in more detail in due consideration of examples of various thermal treatment paths in the phase diagram of the YBCO of FIG. 3. FIGS. 5 and 6 are phase diagrams of an YBCO for explaining methods of forming a superconducting wire according to embodiments of the inventive concept.

A method of forming a superconducting wire according to some embodiments of the inventive concept will be described with reference to FIG. 5.

The superconducting precursor layer is formed on the wire substrate as described above (S30). The REBCO being the superconducting precursor layer may be decomposed into the “100” and the “L”. Here, the “L” is a solid phase at a low temperature, and the main element of the solid phase is the “012”. In other words, the solid phase of the “012” appears in the decomposing process of the REBCO.

The wire substrate on which the superconducting precursor layer is deposited may be thermally treated (S40). The thermal treatment process may be performed according to paths of the phase diagram of FIG. 5. A thermal treatment process according to a path 1 is performed under a relatively lower oxygen partial pressure (e.g., within a range of about 1×10⁻⁵ Torr to about 1×10⁻⁴ Torr). The thermal treatment temperature may increase from a room temperature to about 800° C.

The oxygen partial pressure and/or the thermal treatment temperature may be controlled according to a path 2 of the phase diagram of FIG. 5. For example, the oxygen partial pressure may increase within a range of about 1×10⁻² Torr to about 3×10⁻¹ Torr. For example, the thermal treatment temperature may be equal to or greater than about 800° C. Here, the “L” and the “100” may coexist in the REBCO.

The oxygen partial pressure and/or the thermal treatment temperature may be controlled according to a path 3 of the phase diagram of FIG. 5, so that the REBCO can pass through the boundary I. Thus, a stable epitaxial REBCO layer can be formed. For example, the oxygen partial pressure may be within a range of about 5×10⁻² Torr to about 3×10⁻¹ Torr. The thermal treatment temperature may be reduced to a temperature lower than about 800° C., for example, a room temperature. In more detail, nuclei can be generated from the coexisting “L” and “100” on the surface of the wire substrate and then the REBCO layer can be epitaxial-grown from the nuclei.

FIG. 6 is a phase diagram of YBCO illustrating a method of forming a superconducting wire according to other embodiments of the inventive concept.

A method of forming a superconducting wire according to other embodiments of the inventive concept will be described with reference to FIG. 6. For the purposes of ease and convenience, the descriptions to the same technical features in the above embodiments will be omitted or mentioned briefly.

The superconducting precursor layer is formed on the wire substrate as described in the above embodiments (S30). The wire substrate having the superconducting precursor layer is thermally treated (S40). The thermal treatment process may be performed according to paths of the phase diagram of FIG. 6. The thermal treatment according to a path 1 may be performed under an oxygen partial pressure within a range of, for example, about 5×10⁻² Torr to about 3×10⁻¹ Torr. The thermal treatment temperature may increase from a room temperature to about 800° C. or more. The oxygen partial pressure and/or the thermal treatment temperature may be controlled according to the path 1. Here, the “L” of the liquid phase and the “100” may coexist in the REBCO.

The oxygen partial pressure and/or the thermal treatment temperature may be controlled according to the path 2 of the phase diagram of FIG. 6, so that the REBCO can pass through the boundary I. Thus, a stable epitaxial REBCO layer can be formed. For example, the oxygen partial pressure may be within a range of about 5×10⁻² Torr to about 3×10⁻¹ Torr. The thermal treatment temperature may be reduced to a temperature lower than about 800° C., for example, a room temperature. In more detail, nuclei can be generated from the coexisting “L” and “100” on the surface of the wire substrate and then the REBCO layer can be epitaxial-grown from the nuclei.

A growth process of the REBCO layer according to aforementioned embodiments may be similar to a liquid phase epitaxy (LPE) growth method. Meanwhile, FIGS. 3, 5, and 6 show the phase diagram of the YBCO. Thus, the inventive concept is not limited to the above examples of the oxygen partial pressure and the thermal treatment temperature. In other embodiments, the oxygen partial pressure and the thermal treatment temperature may be changed according to a kind of the rare earth element (RE).

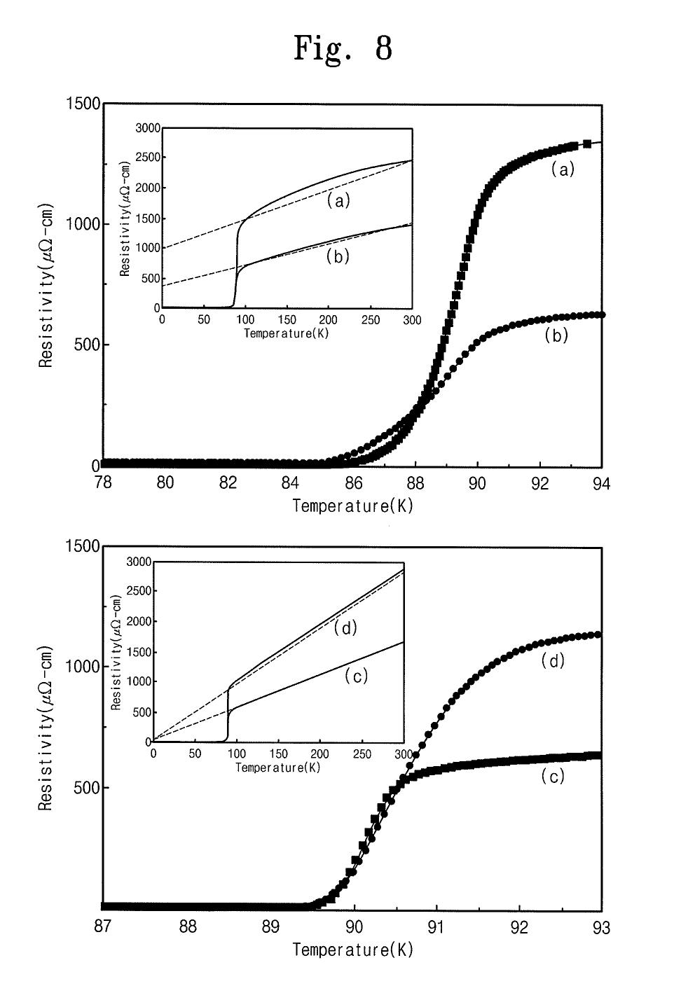

FIG. 7 shows x-ray diffraction (XRD) patterns of a superconducting layer formed according to the inventive concept. FIG. 8 shows resistivity-temperature properties of a superconducting layer formed according to the inventive concept. A substrate used in a test was a LAO (100) substrate and the formed superconducting layer was an YBCO. A reference designator (a) represents a general thermal treatment process with a ramping rate of 20° C./min, and a reference designator (b) represents a general thermal treatment process with a ramping rate of about 240° C./min. A reference designator (c) represents the partial melting process with a ramping rate of about 240° C./min according to the inventive concept, and a reference designator (d) represents the partial melting process with a ramping rate of about 850° C./min according to the inventive concept.

Referring to FIG. 7, large (200) peaks caused by an YBCO grain aligned in an a-axis were observed and small (103) peaks were observed in the general thermal treatment processes (a) and (b). On the other hand, only small (200) peaks were observed in the partial melting processes (c) and (d) of the inventive concept. This means that the superconducting layer mostly consists of YBCO grains aligned in a c-axis and has a little bit of grains aligned in the a-axis. In the general thermal treatment processes (a) and (b), the superconducting layer is directly heated at a firing temperature. Thus, YBCO crystallization occurs at a temperature lower than the firing temperature. The YBCO may be crystallized at the low temperature in random directions, so that the a-axis aligned grains may be grown at a boundary between the substrate and the superconducting layer.

Referring to FIG. 8, in the general thermal treatment processes (a) and (b), resistivities at OK by extrapolation of a resistivity gradient in a normal state do not approach 0 (zero). On the other hand, in the partial melting processes (c) and (d) according to the inventive concept, resistivities at OK by extrapolation approach 0 (zero). According to the partial melting processes (c) and (d) of the inventive concept, a critical temperature (Tc) was about 87K.

According to embodiments of the inventive concept, the superconducting wire with excellent quality may be formed.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of forming a superconducting wire, comprising:
dissolving a superconducting material in an acid not including fluorine to form a superconducting precursor solution;
providing the superconducting precursor solution on a substrate to form a superconducting precursor layer; and
controlling an oxygen partial pressure of a processing chamber provided with the substrate and/or a temperature of the substrate such that the superconducting precursor layer partially have a liquid phase, thereby forming an epitaxial superconducting layer on the substrate.

2. The method of claim 1, wherein the acid not including fluorine includes propionic acid.

3. The method of claim 1, wherein the superconducting material is a superconducting powder.

4. The method of claim 3, wherein the superconducting powder includes rare earth element, barium, and copper.

5. The method of claim 1, wherein controlling an oxygen partial pressure of a processing chamber provided with the substrate and/or a temperature of the substrate comprises:
heating the substrate under an oxygen atmosphere to about 825° C. or more.
